(19) United States
(12) Patent Application Publication
(10) Pub. No.: US 2022/0130707 A1
(43) Pub. Date: Apr. 28, 2022

(54) TRANSFER SUBSTRATE

(71) Applicant: Japan Display Inc., Tokyo (JP)

(72) Inventor: Keisuke ASADA, Tokyo (JP)

(73) Assignee: Japan Display Inc., Tokyo (JP)

(21) Appl. No.: 17/568,721

(22) Filed: Jan. 5, 2022

Related U.S. Application Data
(63) Continuation of application No. PCT/JP2020/023836, filed on Jun. 17, 2020.

(30) Foreign Application Priority Data
Jul. 19, 2019 (JP) 2019-133742

(51) Int. Cl. H01L 21/683; H01L 25/075; H01L 33/62

(52) U.S. Cl. CPC H01L 21/6835; H01L 25/0753; H01L 2933/0066; H01L 2221/68354; H01L 2221/68368; H01L 33/62

(57) ABSTRACT

A transfer substrate for an element includes a support and an elastic body. The support includes a first surface including a first opening portion and a second surface located on the opposite side of the first surface and having a groove portion. The elastic body includes a third surface closing an upper surface of the groove portion and a fourth surface located on the opposite side of the third surface and including a plurality of projection portions. Each of the plurality of projection portions includes a second opening portion. The first opening portion and the second opening portion are penetrated via the groove portion.

### CROSS-REFERENCE TO RELATED APPLICATIONS

The present application is a continuation application of International Patent Application No. PCT/JP2020/023836, filed Jun. 17, 2020, which claims priority to Japanese Patent Application No. 2019-133742, filed Jul. 19, 2019, the entire contents of each are incorporated herein by reference.

### BACKGROUND OF THE INVENTION

### Field

One embodiment of the present invention relates to a transfer substrate that sucks and picks up an element from an element substrate on which the element is formed and transfers the element to a circuit substrate on which a circuit for driving the element is formed.

### Description of the Related Art

In a small or medium-sized display device such as a smart phone, a display using liquid crystals or OLEDs (Organic Light Emitting Diodes) has been commercialized. In particular, an OLED display device using the OLEDs which are self-light emitting elements has the advantages of high-contrast and no need for a backlight, as compared with a liquid crystal display device. However, since the OLEDs are composed of organic compounds, it is difficult to secure high reliability of the OLED display device due to deterioration of the organic compounds.

On the other hand, a so-called micro LED display in which minute micro LEDs are placed in pixels arranged in a matrix has been developed as a next-generation display. The micro LEDs are self-emitting elements similar to the OLEDs, but unlike OLEDs, the micro LEDs are composed of inorganic compounds containing gallium (Ga) or indium (In). Therefore, it is easier to ensure a highly reliable micro LED display as compared with the OLED display. In addition, micro LEDs have high light emission efficiency and high brightness. Therefore, the micro LED display is expected to be the next generation display with high reliability, high brightness, and high contrast.

The micro LEDs are formed on a substrate such as sapphire similar to typical LEDs, and are separated into individual micro LEDs by dicing the substrate. In the micro LED display, it is necessary to place the diced micro LEDs in the pixels of a circuit substrate (also referred to as a backplane or a TFT substrate). As one of the methods for placing the micro LEDs on the circuit substrate, a transfer substrate is used to pick up a plurality of micro LEDs from an element substrate, the transfer substrate is attached to the circuit substrate, and the plurality of micro LEDs are transferred to the circuit substrate (See, for example, U.S. Patent Application Publication No. 2016/0240516 or U.S. Patent Application Publication No. 2017/0047306). In addition, a method using vacuum suction is known for picking up an element or a substrate (see, for example, U.S. Patent Application Publication No. 2013/03097992 or U.S. Pat. No. 8,261,660).

### SUMMARY OF THE INVENTION

A transfer substrate for an element according to an embodiment of the present invention includes a support and an elastic body. The support includes a first surface including a first opening portion and a second surface located on the opposite side of the first surface and having a groove portion. The elastic body includes a third surface closing an upper surface of the groove portion and a fourth surface located on the opposite side of the third surface and including a plurality of projection portions. Each of the plurality of projection portions includes a second opening portion. The first opening portion and the second opening portion are penetrated via the groove portion.

A transfer substrate for an element according to an embodiment of the present invention includes a support and an elastic body. The support includes a first surface including a first opening portion and a second opening portion and a second surface located on an opposite side of the first surface and including a first groove portion and a second groove portion. The elastic body includes a third surface closing an upper surface of the first groove portion and an upper surface of the second groove portion and a fourth surface located on an opposite side of the third surface and including a first projection portion and a second projection portion. The first projection portion includes a third opening portion. The second projection portion includes a fourth opening portion. The first opening portion and the third opening portion are penetrated via the first groove portion. The second opening portion and the fourth portion are penetrated via the second groove portion.

### BRIEF DESCRIPTION OF THE DRAWINGS

FIG. 1A is a schematic perspective view of a transfer substrate according to an embodiment of the present invention;

FIG. 1B is a schematic perspective view of a transfer substrate according to an embodiment of the present invention;

FIG. 2A is a schematic cross-sectional view of a transfer substrate according to an embodiment of the present invention;

FIG. 2B is a schematic cross-sectional view of a transfer substrate according to an embodiment of the present invention;

FIG. 2C is a schematic cross-sectional view of a transfer substrate according to an embodiment of the present invention;

FIG. 3 is a schematic perspective view of a support of a transfer substrate according to an embodiment of the present invention;

FIG. 4 is a schematic plan view of a support of a transfer substrate according to an embodiment of the present invention;

FIG. 5 is a schematic plan view of a support of a transfer substrate according to an embodiment of the present invention;

FIG. 6 is a schematic plan view of a support of a transfer substrate according to an embodiment of the present invention;

FIG. 7A is a schematic cross-sectional view of a transfer substrate according to an embodiment of the present invention;

FIG. 7B is a schematic cross-sectional view of a transfer substrate according to an embodiment of the present invention;

FIG. 8A is a schematic cross-sectional view of a transfer substrate according to an embodiment of the present invention:

FIG. 8B is a schematic cross-sectional view of a transfer substrate according to an embodiment of the present invention;

FIG. 8C is a schematic cross-sectional view of a transfer substrate according to an embodiment of the present invention;

FIG. 9 is a schematic perspective view of a support of a transfer substrate according to an embodiment of the present invention;

FIG. 10 is a schematic perspective view of an element substrate used in a method for transferring an element according to an embodiment of the present invention;

FIG. 11 is a block diagram showing a layout configuration of a circuit substrate used in a method for transferring an element according to an embodiment of the present invention;

FIG. 12 is a schematic cross-sectional view of a TFT of a circuit substrate used in a method for transferring an element according to an embodiment of the present invention:

FIG. 13 is a flowchart of a method for transferring an element according to an embodiment of the present invention;

FIG. 14A is a schematic cross-sectional view showing a method for transferring an element according to an embodiment of the present invention;

FIG. 14B a schematic cross-sectional view showing a method for transferring an element according to an embodiment of the present invention;

FIG. 14C a schematic cross-sectional view showing a method for transferring an element according to an embodiment of the present invention;

FIG. 14D a schematic cross-sectional view showing a method for transferring an element according to an embodiment of the present invention;

FIG. 14E a schematic cross-sectional view showing a method for transferring an element according to an embodiment of the present invention;

FIG. 14F a schematic cross-sectional view showing a method for transferring an element according to an embodiment of the present invention;

FIG. 14G a schematic cross-sectional view showing a method for transferring an element according to an embodiment of the present invention; and

FIG. 14H a schematic cross-sectional view showing a method for transferring an element according to an embodiment of the present invention.

### DESCRIPTION OF EMBODIMENTS

In general, a transfer substrate for a minute element such as a micro LED is smaller than an element substrate or a circuit substrate. Therefore, in the case of vacuum suction using such a transfer substrate, it is difficult to sufficiently vacuum exhaust a minute space in the transfer substrate. In addition, a large-scale device such as a vacuum pump is required for vacuum suction.

In view of the above problems, it is one object of the present invention to provide a transfer substrate that can pick up and release a minute element without requiring a large-scale device.

Hereinafter, embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In each embodiment of the present invention, although the term “over” or “below” is used for convenience of explanation, the vertical relationship in the explanation may be reversed. For example, the expression “element over a substrate” merely explains the vertical relationship between the substrate and the element, and another member may be placed between the substrate and the element.

In the specification, the expressions “α includes A, B or C”, “α includes any of A, B and C”, and “α includes one selected from the group consisting of A, B and C” do not exclude the case where α includes a plurality of combinations of A to C unless otherwise specified. Further, these expressions do not exclude the case where α includes other elements.

In the specification, an element is, for example, a microelectromechanical system (MEMS), a laser diode (LD), a mini LED, or a micro LED, or the like, but is not limited thereto.

### First Embodiment

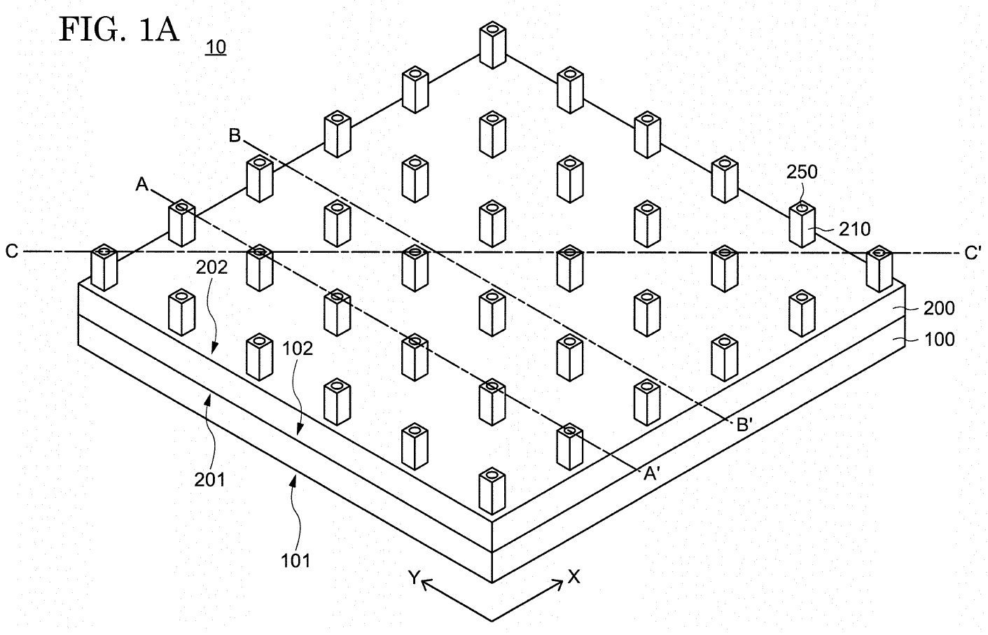

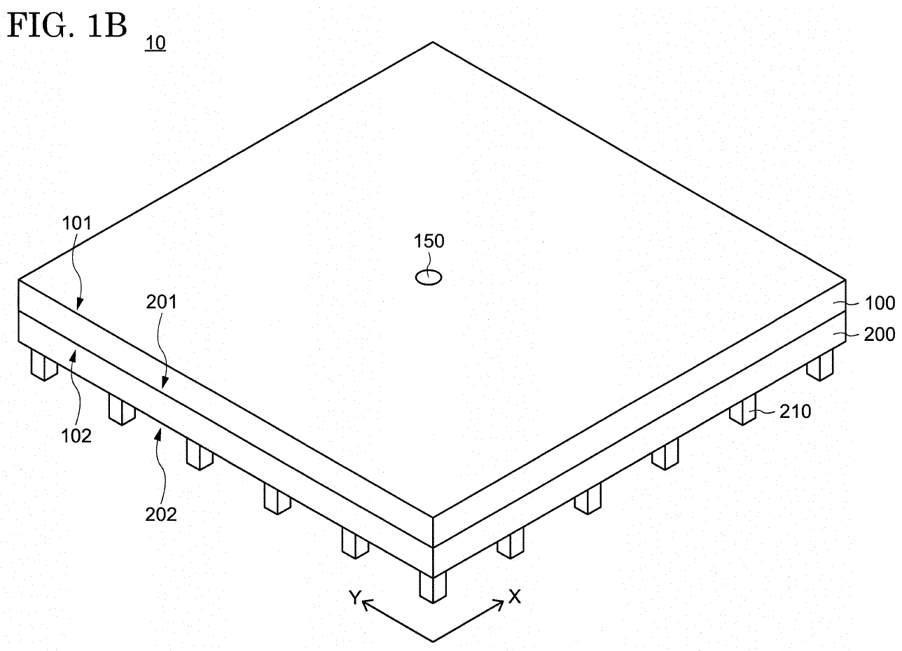

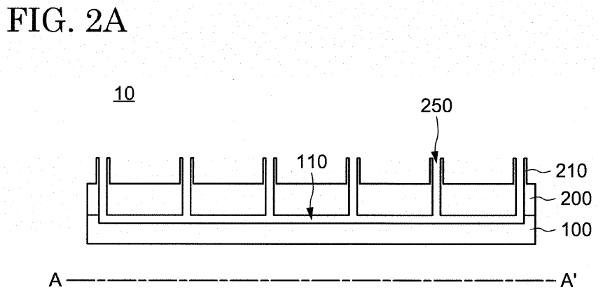

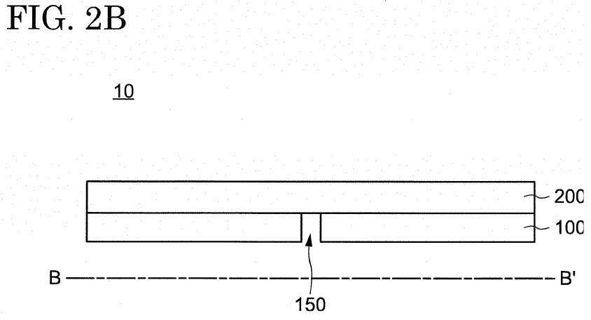

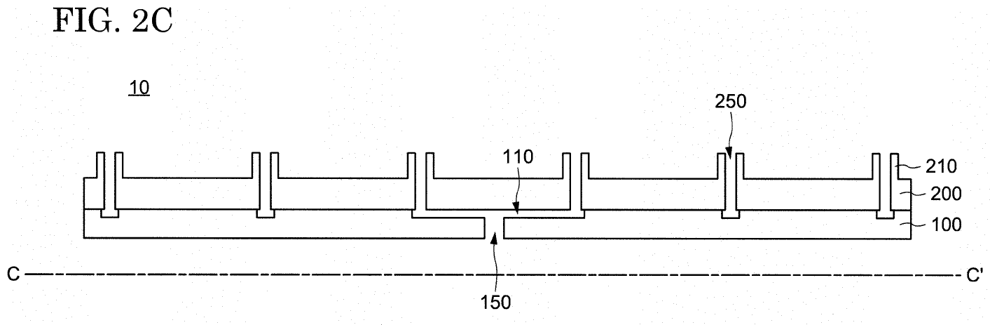

A transfer substrate 10 for an element according to an embodiment of the present invention is described with reference to FIGS. 1A to 2C.

### [Structure]

FIGS. 1A and 1B are schematic perspective views of the transfer substrate 10 for the element according to the embodiment of the present invention. FIG. 1A is a schematic perspective view seen from an elastic body 200 side. On the other hand, FIG. 1B is a schematic perspective view seen from a support 100 side.

As shown in FIGS. 1A and 1B, the transfer substrate 10 for the element includes a support 100 and an elastic body 200 on the support 100. The support 100 includes a first surface 101 and a second surface 102 located on the opposite side of the first surface 101. The elastic body 200 includes a third surface 201 and a fourth surface 202 located on the opposite side of the third surface 201. The second surface 102 of the support 100 and the third surface 201 of the elastic body 200 are in contact with each other. The second surface 102 of the support 100 and the third surface 201 of the elastic body 200 may be in contact with each other via an adhesive.

A first opening portion 150 is provided at the center of the first surface 101 of the support 100.

A plurality of projection portions 210 are provided on the fourth surface 202 of the elastic body 200. Further, a second opening portion 250 is provided in each of the plurality of projection portions 210.

The size of the transfer substrate 10 can be appropriately determined in consideration of the size of a substrate on which the element is formed (hereinafter referred to as “first substrate”) or the size of a substrate on which the element is transferred (hereinafter referred to as “second substrate”). The size of the transfer substrate 10 can also be made significantly smaller than the sizes of the first substrate and the second substrate. For example, the size of the transfer substrate 10 is 50 mm square, but not limited to this. Further, for example, a shape of the transfer substrate 10 is a rectangle, but not limited to this. The shape of the transfer substrate 10 can be polygonal, circular, elliptical, or the like.

It is preferable that an edge surface of the support 100 and an edge surface of the elastic body 200 of the transfer substrate 10 are aligned, but the transfer substrate 10 is not limited to this. The support 100 may be provided larger than the elastic body 200, or may be provided smaller than the elastic body 200. It is preferable that the support 100 is provided so as to uniformly transmit a force to the elastic body 200 when the force is applied to the support 100.

The projection portion 210 has a certain width in a first direction (X direction in FIG. 1) and a second direction (Y direction in FIG. 1), and is provided to project from the fourth surface 202 of the elastic body 200 so as to have a certain height in a direction perpendicular to the fourth surface 202 of the elastic body 200 (the vertical direction with respect to the X direction and the Y direction). The width of the projection portion 210 in the first direction and the second direction can be appropriately determined in consideration of the size of the element picked up from the first substrate. Further, the height (or the vertical distance) of the projection portion 210 can be appropriately determined in consideration of the height of the element picked up from the first substrate. The height of the projection portion 210 is, for example, greater than or equal to 1 μm and less than or equal to 100 μm, preferably greater than or equal to 5 μm and less than or equal to 50 μm, and particularly preferably greater than or equal to 10 μm and less than or equal to 20 μm from the third surface 201 of the elastic body 200. If the height of the projection portion 210 exceeds 100 μm, the projection portion 210 is likely to be deformed in a direction other than the vertical direction when the picked-up element is transferred to the second substrate, so that a deviation of a bonding position of the element becomes large. Further, if the height of the projection portion 210 is smaller than 1 μm, when the element is picked up from the first substrate, the element is in close contact not only with the projection portion 210 but also with the fourth surface 202 of the elastic body 200. Therefore, the height of the projection portion 210 is preferably in the above range.

The projection portion 210 has an upper surface 211 (hereinafter referred to as “head surface 211”). The head surface 211 has a function of being in contact with and picking up the element. Therefore, the head surface 211 has an adhesive strength that allows the element to be peeled off from the first substrate. The head surface 211 is preferably as flat as possible, and a surface roughness of the head surface 211 is preferably less than or equal to 1 μm. When the head surface 211 is flat, a contact area between the head surface 211 and the element increases, so that adhesion between the head surface 211 and the element can be increased. In other words, the adhesive strength of the head surface 211 can be increased by reducing the surface roughness of the head surface 211.

The projection portion 210 may have a certain width in the first direction and the second direction. A cross-sectional shape of the projection portion 210 does not have to be rectangular. For example, the cross-sectional shape of the projection portion 210 can be polygonal, circular, or elliptical. That is, the projection portion 210 can have various shapes such as a polygonal pillar, a cylinder, or an elliptical pillar. Further, the projection portion 210 may be provided with a taper toward the head surface 211.

The number and spacing of the projection portions 210 can be appropriately determined in consideration of the size of the element to be picked up and a spacing of an arrangement of the elements of the second substrate to be transferred. For example, the projection portions 210 can be arranged in a matrix.

FIG. 2A to 2C are schematic cross-sectional views of the transfer substrate 10 for the element according to the embodiment of the present invention. Specifically, FIG. 2A is a schematic cross-sectional view of the transfer substrate 10 cut along the line A-A′ of FIG. 1A, FIG. 2B is a schematic cross-sectional view of the transfer substrate 10 cut along the line B-B′ of FIG. 1A, and FIG. 2C is a schematic cross-sectional view of the transfer substrate 10 cut along the line C-C′ of FIG. 1A.

A groove portion 110 is provided on the second surface 102 of the support 100, and an upper surface of the groove portion 110 is closed by the third surface 201 of the elastic body 200. The first opening portion 150 and the second opening portion 250 are connected to the groove portion 110. That is, the first opening portion 150 and the second opening portion 250 penetrate through the groove portion 110. Therefore, when the first opening portion 150 and the second opening portion 250 are closed, the inside of the first opening portion 150, the second opening portion 250, and the groove portion 110 becomes a closed space. Although not shown, a means for closing the first opening portion 150 such as a cap, for example, may be provided.

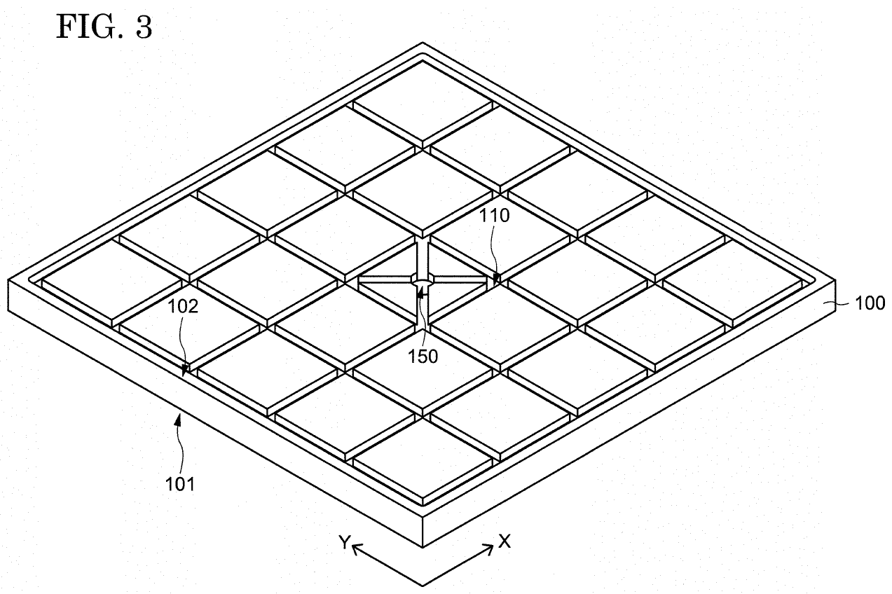

A configuration of the groove portion 110 is described in detail with reference to FIG. 3.

FIG. 3 is a schematic perspective view of the support 100 of the transfer substrate 10 for the element according to the embodiment of the present invention. Specifically, FIG. 3 is a perspective view of the elastic body 200 removed from the transfer substrate 10 and seen from the second surface 102 of the support 100.

The groove portion 110 is formed by combining a plurality of straight portions extending in the first direction (X direction) corresponding to one side of the support 100, in the second direction (Y direction) perpendicular to the first direction, or in in a diagonal direction of the support 100. For example, in the groove portion 110 shown in FIG. 3, six straight portions extending in the X direction and six straight portions extending in the Y direction intersect. Although not shown in the figure, a second opening portion 250 of the elastic body 200 is provided at the intersection of the straight line portion in the X direction and the straight line portion in the Y direction. In addition, in the central portion of the support 100, two straight portions which extend diagonally of the support 100 intersect. A first opening portion 150 is provided at the intersection of the diagonal straight portions. Further, although FIG. 3 shows the case where the first opening portion 150 and the second opening portion 250 are provided at the intersection of the straight portions, the present invention is not limited to this example. The groove portion 110 forms a path so that air in the second opening portion 250 can be discharged from the first opening portion 150 or the air sucked from the first opening portion 150 can be discharged from the second opening 250. As a result, the first opening portion 150 and the second opening portion 250 may be provided at any portion on the straight line portion.

A cross-sectional shape of the groove portion 110 is rectangular and the groove portion 110 includes a side surface and a bottom surface. A width of the groove portion 110 can be appropriately determined in consideration of a diameter of the first opening portion 150 or a diameter of the second opening portion 250, but is preferably larger than the diameter of the second opening portion 250. For example, the width of the groove portion 110 is less than or equal to 500 μm, preferably greater than or equal to 100 μm and less than or equal to 400 μm, and particularly preferably greater than or equal to 200 μm and less than or equal to 300 μm. Further, the number and spacing of the groove portions 110 can be appropriately determined in consideration of the size of the element and a spacing of an arrangement of the elements of the substrate to be transferred. Furthermore, the groove portion 110 may be tapered toward the bottom surface. The diameter of the second opening portion 250 is, for example, greater than or equal to 10 μm and less than or equal to 30 μm, and the diameter of the first opening portion 150 is, for example, greater than or equal to 5000 μm and less than or equal to 10,000 μm.

The depth of the groove portion 110 is not particularly limited, but if the depth of the groove portion 110 is large, the support 100 has less rigidity. Therefore, the depth of the groove portion 110 is preferably less than or equal to ½ of the thickness of the support 100.

The bottom surface of the groove portion 110 is not limited to a flat surface and may be a curved surface. Further, the groove portion 110 may be provided on only the side surface without providing a bottom surface. The groove portion 110 may have a path formed so that air in the second opening portion 250 can be discharged from the first opening portion 150, or so that air sucked from the first opening portion 150 can be discharged from the second opening portion 250. Therefore, the cross-sectional shape of the groove portion 110 can be not only rectangular but also polygonal such as triangular or a pentagonal, circular, or elliptical.

### [Material]

The support 100 is provided with the grove portion 110, and has a function of supporting the elastic body 200 and increasing the rigidity of the transfer substrate 10 in the portion where the groove portion 110 is not provided. Therefore, the support 100 is preferably made of a material that is harder than the elastic body 200. For example, quartz, glass, sapphire, silicon, stainless steel, or the like can be used as a material of the support 100.

The elastic body 200 has a function of absorbing a repulsive force from the element when the projection portion 210 picks up or releases the element. For example, a natural rubber (NR), a silicone rubber (SI), a polyurethane rubber (PUR), a fluororubber (FPM), nitrile rubber (NBR), a styrene-butadiene rubber (SBR), a butadiene rubber. (BR), an isoprene rubber (IR), an ethylene propylene diene rubber (EPDM), an acrylic rubber (ACM), an isobutyene isoprene rubber (IIR), or the like, or materials made of these rubbers alone or in combination can be used for the elastic body 200. In particular, when high heat resistance is required, the material of the elastic body 200 is preferably silicone rubber or fluororubber. In the present specification, the silicone rubber includes a polydimethylsiloxane (PDMS).

Further, the elastic body 200 may contain additives such as a vulcanizing material, a filler, a softener, a coloring agent, or an anti-deterioration agent. Sulfur, a sulfur compound, a peroxide, or the like can be used as the vulcanizing material. Barium sulfate, calcium carbonate, silicic acid, magnesium silicate, calcium silicate, or the like can be used as the filler. Paraffin-based process oil, naphthenic process oil, or the like can be used as the softener. Carbon black, titanium white, ultramarine blue, phthalocyanine, red iron oxide, lead chromate, or the like can be used as the coloring agent. Phenol, wax, or the like can be used as the anti-deterioration agent.

Further, the elastic body 200 may contain a vulcanization aid or a vulcanization accelerator. Zinc stearate, stearate, zinc white, zinc oxide, magnesium oxide, or the like can be used as the vulcanization aid. Thiazoles, thiraums, sulfenamides, dithiocarbamate, or the like may be used as the vulcanization accelerator.

The third surface 201 of the elastic body 200 and the second surface 102 of the support 100 may be adhered to each other by using an adhesive. Acrylic resin, polyester resin, vinyl chloride/vinyl acetate copolymer resin, ethylene/acrylic acid ester copolymer resin, ethylene/methacrylate copolymer resin, polyamide resin, polyolefin resin, chlorinated polyolefin resin, epoxy resin, urethane resin, or the like can be used as the adhesive.

In the transfer substrate 10 for the element according to the present embodiment, the element can be sucked or released by deforming the projection portion 210 to change the volume in the second opening portion 250. Therefore, the element can be picked up or released without the need for a special apparatus, and the yield in manufacturing the device including the element is improved.

### [Modification 1]

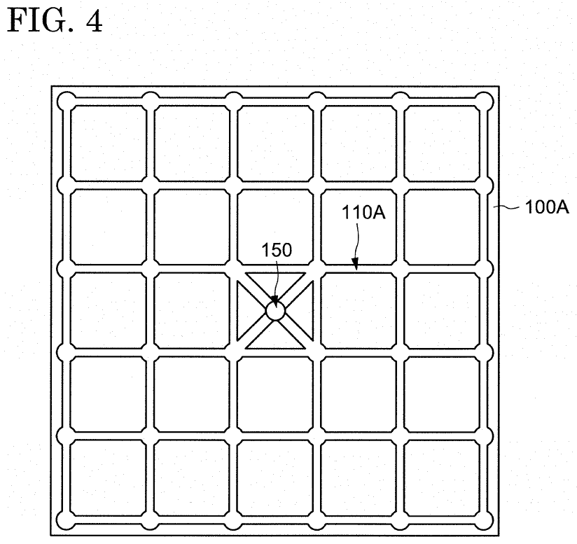

A modified example of the transfer substrate 10 for the element according to the present embodiment is described with reference to FIG. 4.

FIG. 4 is a schematic plan view of a support 100A of the transfer substrate 10A for the element according to an embodiment of the present invention. The transfer substrate 10A includes a support 100A and an elastic body 200. Since the elastic body 200 of the transfer substrate 10A has the same configuration as that of the transfer substrate 10, the description thereof is omitted here. Therefore, in the following explanation, in order to explain the support 100A of the transfer substrate 10A having a configuration different from that of the transfer substrate 10, FIG. 4 shows a plan view of the support 100A seen from a second surface 102A of the support 100A by removing the elastic body 200 in contact with the second surface 102A of the support 100A from the support 100A.

As shown in FIG. 4, a groove portion 110A is provided on the second surface 102A of the support 100A. In the groove portion 110A, a first straight line portion extending in the X direction and a second straight line portion extending in the Y direction intersect (or are orthogonal to each other). A width of the intersection of the first straight line portion and the second straight line portion is provided to be larger than a width of the first straight line portion and a width of the second straight line portion. In other words, a circular groove is formed at the intersection of the first straight section and the second straight section, and a diameter of the circular groove is larger than the width of the first straight section and the width of the second straight section. FIG. 4 shows an example of a circular groove portion at the intersection of the first straight line portion and the second straight line portion, but is not limited to this example. An elliptical groove portion or a polygonal groove including a rectangle may be formed at the intersection of the first straight line portion and the second straight line portion.

In the transfer substrate 10A for the element according to the present embodiment, in the groove portion 110A, the width of the intersection of the straight line portions is formed to be larger than the width of the straight line portions. Therefore, even when the support 100A and the elastic body 200 are bonded to manufacture the transfer substrate 10A, the second opening portion 250 of the elastic body 200 is easily aligned with the intersection of the groove portions 110A of the support 100A. That is, when the transfer substrate 10A is manufactured, the alignment accuracy of the bonding between the support 100A and the elastic body 200 can be improved.

### [Modification 2]

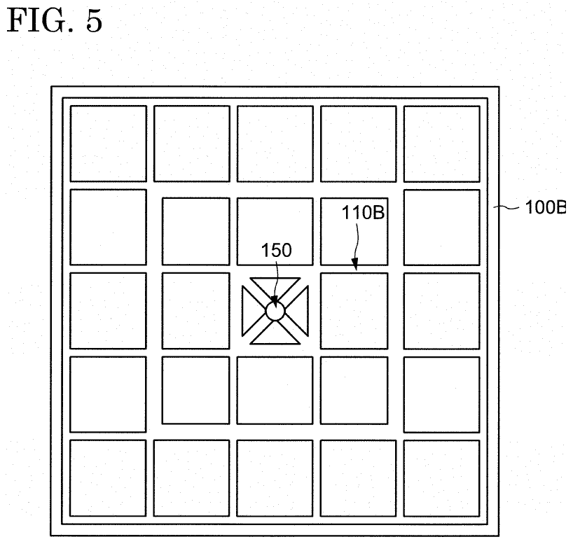

A modified example of the transfer substrate 10 for the element according to the present embodiment is described with reference to FIG. 5.

FIG. 5 is a schematic plan view of a support 100B of the transfer substrate 10B for the element according to an embodiment of the present invention. The transfer substrate 10B includes a support 100B and an elastic body 200. Since the elastic body 200 of the transfer substrate 10B has the same configuration as that of the transfer substrate 10, the description thereof is omitted here. Therefore, in the following explanation, in order to explain the support 100B of the transfer substrate 10B having a configuration different from that of the transfer substrate 10, FIG. 5 shows a plan view of the support 100B seen from a second surface 102B of the support 100B by removing the elastic body 200 in contact with the second surface 102B of the support 100B from the support 100B.

As shown in FIG. 5, a groove portion 1108 is provided on the second surface 1028 of the support 100B. In the groove portion 1108, a plurality of first straight line portions extending in the X direction and a plurality of second straight line portions extending in the Y direction intersect (or are orthogonal to each other). Each of the first straight line portions and the second straight line portions has different widths in a straight portion located inside and a straight portion located outside in the support 100B. For example, a width of the outer straight portion is smaller than a width of the inner straight portion.

When the element is released from the transfer substrate 10, air is sucked from the first opening portion 150 and is sent to the second opening portion 250. However, if the second opening portion 250 is distant from the first opening portion 150, it may not be possible to send sufficient air to the second opening portion 250 to release the element. Even in such a case, by making the width of the outer straight portion smaller than the width of the inner straight portion in the support 100B, the difference in the amount of air sent between the opening portion 250 closer to the first opening portion 150 and the second opening portion 250 farther from the first opening portion 150 can be adjusted.

In the transfer substrate 10B for the element according to the present embodiment, the width of the straight line portion of the groove portion 110B closer to the first opening 150 is large and the width of the straight portion farther from the first opening portion 150 is small. Therefore, in the transfer substrate 10B, the element can be released even with a slight adjustment of air in the straight portion farther from the first portion 150.

### [Modification 3]

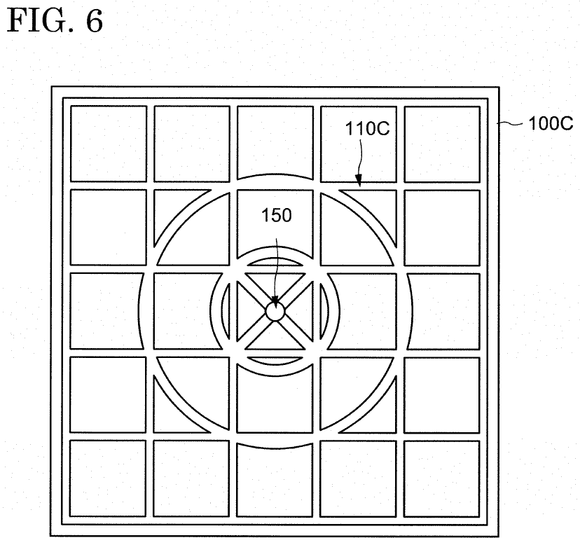

A further modified example of the transfer substrate 10 for the element according to the present embodiment is described with reference to FIG. 6.

FIG. 6 is a schematic plan view of a support 100C of the transfer substrate 10C for the element according to an embodiment of the present invention. The transfer substrate 10C includes a support 100C and an elastic body 200. Since the elastic body 200 of the transfer substrate 10C has the same configuration as that of the transfer substrate 10, the description thereof is omitted here. Therefore, in the following explanation, in order to explain the support 1000 of the transfer substrate 10C having a configuration different from that of the transfer substrate 10, FIG. 6 shows a plan view of the support 1000 seen from a second surface 102C of the support 100C by removing the elastic body 200 in contact with the second surface 102C of the support 1000 from the support 1000.

As shown in FIG. 6, a groove portion 110C is provided on the second surface 102C of the support 1000. The groove portion 110C includes not only a first straight line portion extending in the X direction and a second straight line portion extending in the Y direction intersecting with each other, but also includes a curved portion.

By including the curved portion as well as the straight portion in the groove portion 110C, the amount of air sent from the first opening portion 150 to the second opening portion 250 can be adjusted. In addition, the straight portion of the groove portion 110C shown in FIG. 6 may be a curved portion.

In the transfer substrate 10C for the element according to the present embodiment, the groove portion 110C includes not only the straight portion but also the curved portion, so that an air path is diversified and the amount of air sent from the first opening portion 150 to the second opening portion 250 can be adjusted. Therefore, it is possible to reduce the difference in the amount of air sent between the second opening portion 250 closer to the first opening portion 150 and the second opening portion 250 farther from the first opening portion 150. Therefore, in the transfer substrate 10C, the element can be released even with a slight adjustment of air in the straight portion farther from the first opening portion 150.

The above configurations including the modifications are merely embodiments, and the present invention is not limited to the above configurations.

### Second Embodiment

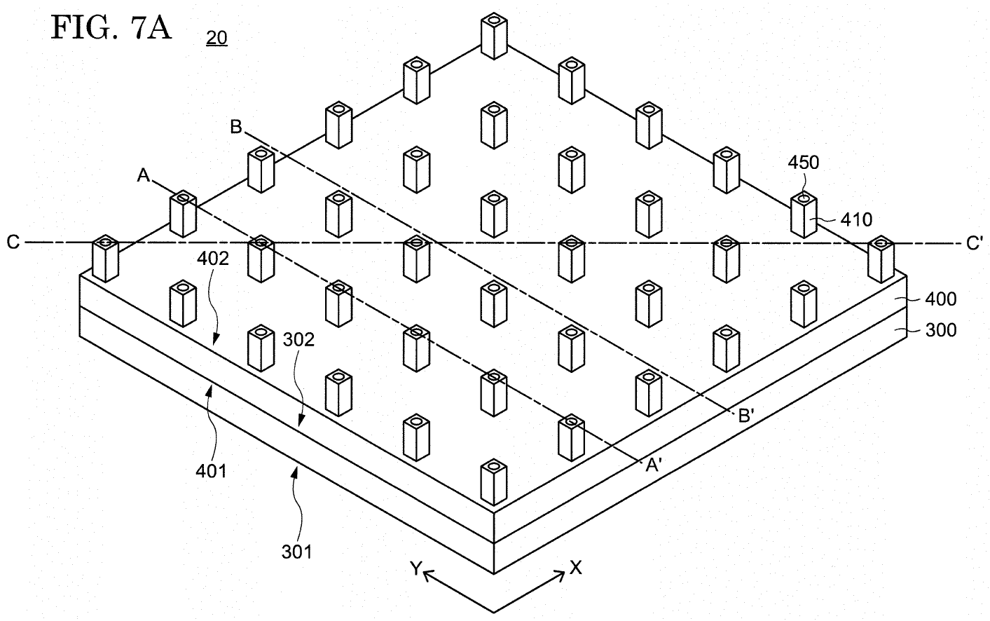

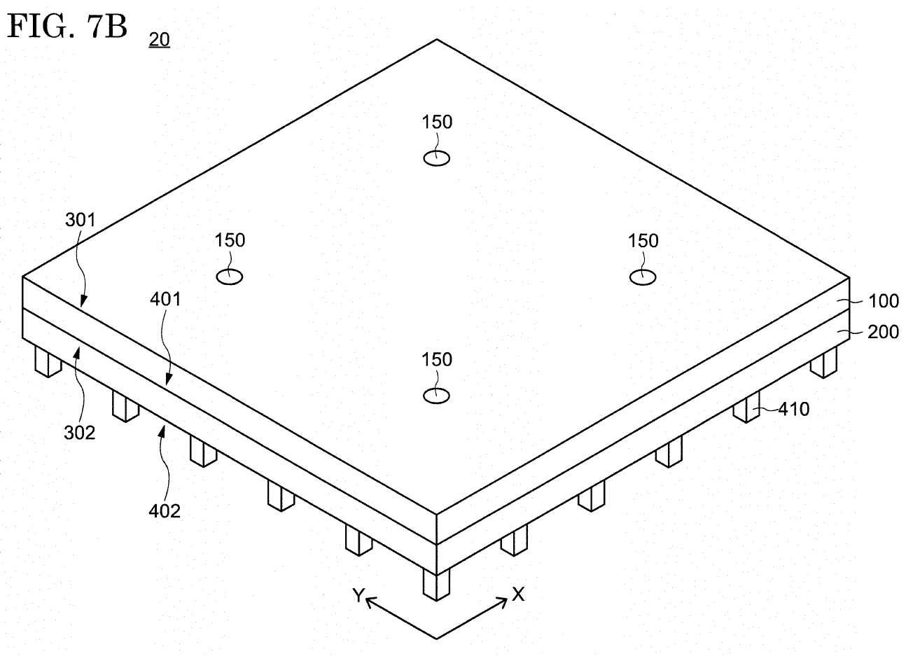

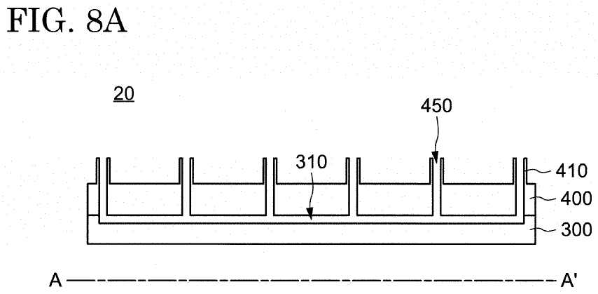

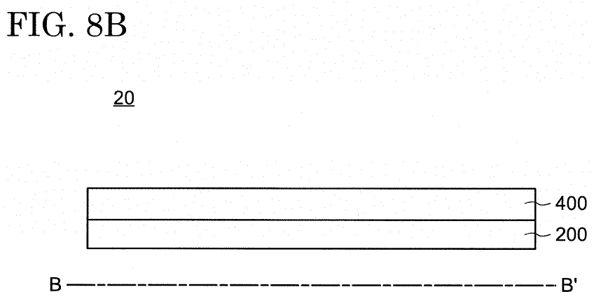

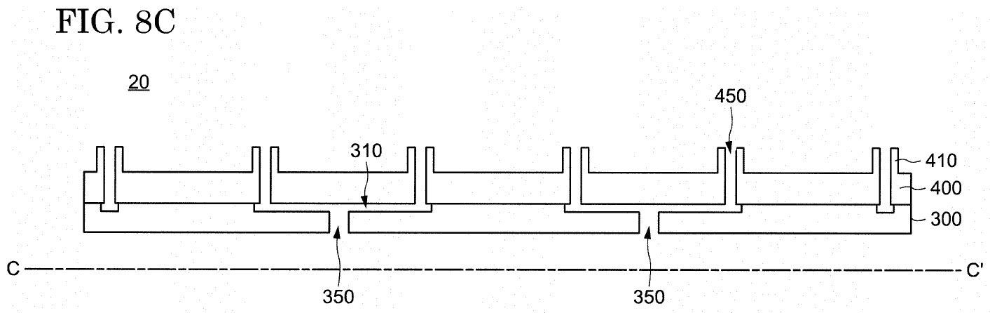

A transfer substrate 20 for an element according to an embodiment of the present invention, which is different from the First Embodiment, is described with reference to FIGS. 7A to 8C. In the following explanation, the description of the same configuration as in the First Embodiment is omitted, and the configuration different from the First Embodiment is mainly described.

FIGS. 7A and 7B are schematic perspective views of the transfer substrate 20 for the element according to the embodiment of the present invention. FIG. 7A is a schematic perspective view seen from an elastic body 400 side. On the other hand, FIG. 1B is a schematic perspective view seen from a support 300 side.

As shown in FIGS. 7A and 71, the transfer substrate 20 for the element includes a support 300 and an elastic body 400 on the support 300. The support 300 includes a first surface 301 and a second surface 302 located on the opposite side of the first surface 301. The elastic body 400 includes a third surface 401 and a fourth surface 402 located on the opposite side of the third surface 401. The second surface 302 of the support 300 and the third surface 401 of the elastic body 400 are in contact with each other. The second surface 302 of the support 100 and the third surface 401 of the elastic body 200 may be in contact with each other via an adhesive.

In the first surface 301 of the support 300, four first opening portions 350 are provided at equal intervals from the center of the support 300. Although not shown in the figure, a means for closing the first opening portions 350 such as a cap, for example, may be provided. The cap may close the four first openings 350 at the same time, or may individually close the four first openings 350.

A plurality of projection portions 410 is provided in a matrix on the fourth surface 402 of the elastic body 400. Further, a second opening 450 is provided in each of the plurality of projection portions 410.

FIG. 8A to 8C are schematic cross-sectional views of the transfer substrate 20 for the element according to the embodiment of the present invention. Specifically. FIG. 8A is a schematic cross-sectional view of the transfer substrate 20 cut along the line A-A′ of FIG. 7A, FIG. 8B is a schematic cross-sectional view of the transfer substrate 20 cut along the line B-B′ of FIG. 7A, and FIG. 8C is a schematic cross-sectional view of the transfer substrate 10 cut along the line C-C′ of FIG. 7A.

A groove portion 310 is provided on the second surface 302 of the support 300, and an upper surface of the groove portion 310 is closed by the third surface 401 of the elastic body 400. The first opening portion 350 and the second opening portion 450 are connected to the groove portion 310. That is, the first opening portion 350 and the second opening portion 450 penetrate through the groove portion 310. Therefore, when the first opening portion 150 and the second opening portion 450 are closed, the inside of the first opening portion 150, the second opening portion 450, and the groove portion 110 becomes a closed space.

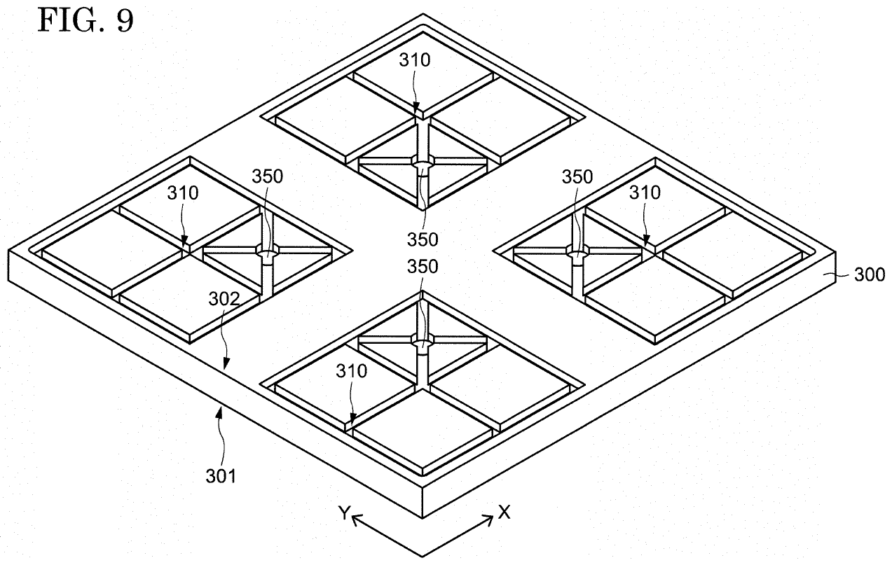

A configuration of the groove portion 310 is described in detail with reference to FIG. 9.

FIG. 9 is a schematic perspective view of the support 300 of the transfer substrate 20 for the element according to the embodiment of the present invention. Specifically, FIG. 9 is a perspective view of the elastic body 400 removed from the transfer substrate 20 and seen from the second surface 302 of the support 300.

The groove portion 310 is formed of four separated portions. Further, the first opening 350 is provided for each of the separated groove portions. Therefore, since the distance between the first opening 350 and the second opening 450 is smaller, the element can be picked up or released with a slight volume adjustment.

In the transfer substrate 20 for the element according to the present embodiment, a plurality of small spaces can be provided in the transfer substrate by separating the groove portion 310. Therefore, the transfer substrate 20 can pick up or release the element with a slight volume adjustment in the spaces.

### Third Embodiment

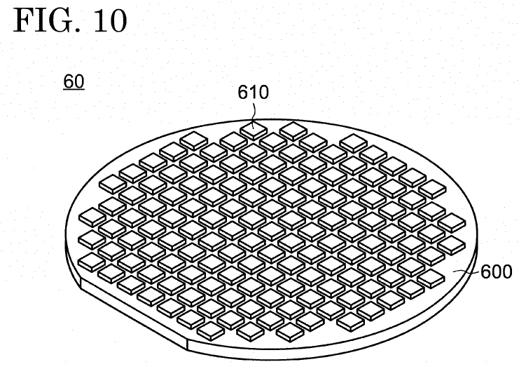

A method for transferring an element according to an embodiment of the present invention is described with reference to FIGS. 10 to 15. Specifically, this embodiment describes a method of transferring an element from an element substrate (first substrate) on which the element is formed to a circuit substrate (second substrate) on which a circuit for driving the element is formed, using the transfer substrate 10 for the element according to the First Embodiment.

### [1. Element Substrate (First Substrate)]

FIG. 10 is a schematic perspective view of an element substrate 60 used in the method for transferring the element according to the embodiment of the present invention.

As shown in FIG. 10, the element substrate 60 includes a support substrate 600 and a plurality of elements 610. Further, the plurality of elements 610 are arranged in a matrix on the support substrate 600, but not limited to this arrangement. The plurality of elements 610 may be arranged in a staggered manner on the support substrate 600.

A rigid substrate such as quartz, glass, or silicon, or a flexible substrate such as polyimide, acrylic, polyethylene naphthalate (PEN), or polyethylene terephthalate (PET) can be used as the support substrate 600. Further, the support substrate 600 is not limited to a substrate, and may be a film or a sheet.

The support substrate 600 may be a base material or a wafer used for manufacturing the element. In the case of an element using a silicon semiconductor, a silicon wafer can be used as the support substrate 600. Further, in the case of an element using a compound semiconductor, a sapphire substrate can be used as the support substrate 600.

Further, the support substrate 600 may be a dicing film or a dicing sheet. After forming the element on the base material or the wafer, the dicing film or the dicing sheet is attached to the base material or the wafer and dicing of the base material or the wafer is performed. In this case, the dicing film or the dicing sheet is the support substrate 600. Further, the element 610 includes the base material or the wafer on which the element is formed.

Furthermore, the elements 610 after dicing the base material or the wafer can be arranged on another substrate, film, or sheet, which can be used as the support substrate 600.

The element substrate 60 is a substrate that serves as a transfer source. The element substrate 60 is not limited to the above configuration. In the element substrate 60, the elements 610 to be transferred may be separately arranged on the support substrate 600 so that the transfer substrate 10 can pick up the elements 610.

### [2. Circuit Substrate (Second Substrate)]

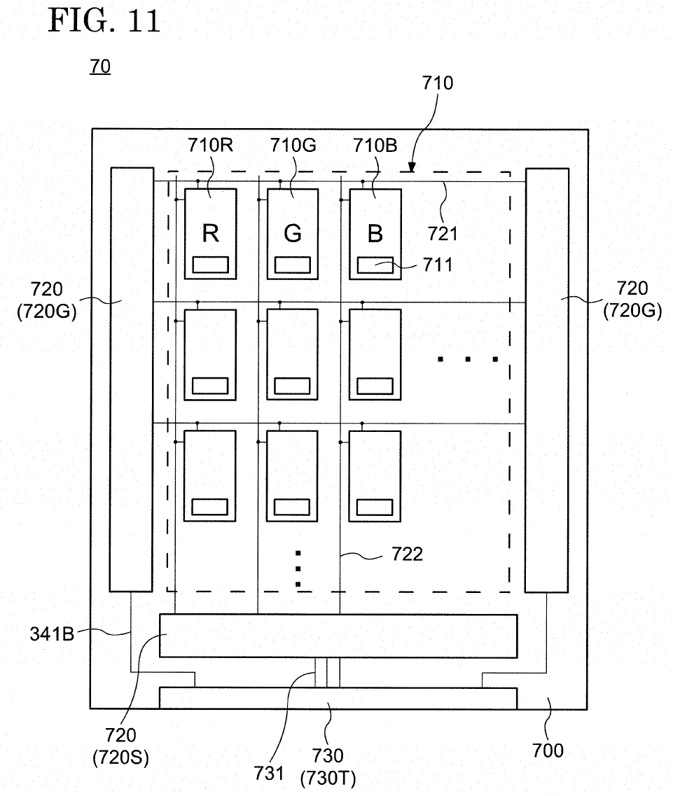

FIG. 11 is a block diagram showing a layout configuration of the circuit substrate 70 used in the method for transferring the element according to the embodiment of the present invention. Specifically, the circuit substrate 70 is for a display device, and FIG. 11 shows regions and a connection relationship provided on the substrate 700 included in the circuit substrate 70. The circuit substrate 70 used in this embodiment is not limited to the display device.

A translucent substrate such as a glass substrate, a quartz substrate, a sapphire substrate, a polyimide substrate, an acrylic substrate, a siloxane substrate, or a fluororesin substrate can be used as the substrate 700. Further, when translucency is not required, a semiconductor substrate such as a silicon substrate, a silicon carbide substrate, or a compound semiconductor substrate, or a conductive substrate such as a stainless steel substrate can be used as the substrate 700.

As shown in FIG. 11, a pixel region 710, a driver circuit region 720, and a terminal region 730 are provided on the substrate 700. The driver circuit region 720 and the terminal region 730 are provided around the pixel region 710.

The pixel region 710 includes a plurality of red light emitting pixels 710R, a plurality of green light emitting pixels 710G, and a plurality of blue light emitting pixels 710B which are arranged in a matrix. A pixel circuit 711 is provided in each of the red light emitting pixel 710R, the green light emitting pixel 710G, and the blue light emitting pixel 710B. Although not shown in the figure, an electrode electrically connected to the element 610 is provided in each of the red light emitting pixel 710R, the green light emitting pixel 710G, and the blue light emitting pixel 710B. Further, although not shown in the figure, a conductive adhesive is provided on the electrode in order to bond the element 610 and the electrode.

The driver circuit region 720 includes a gate driver circuit 720G and a source driver circuit 720S. The pixel circuit 711 and the gate driver circuit 720G are connected via a gate wiring 721. Further, the pixel circuit 711 and the source driver circuit 720S are connected via a source wiring 722. The red light emitting pixel 710R, the green light emitting pixel 710G, and the blue light emitting pixel 710B are provided at positions where the gate wiring 721 and the source wiring 722 intersect.

The terminal region 730 includes a terminal portion 730T for connecting to an external device. The terminal portion 730T and the gate driver circuit 720G are connected through a connection wiring 731. Further, the terminal portion 730T and the source driver circuit 720S are connected through a connection wiring 732. By connecting a flexible printed circuit substrate (FPC) or the like which is connected to the external device, to the terminal portion 730T, the external device and the circuit substrate 70 are connected. Each pixel circuit 711 provided on the circuit substrate can be driven by a signal from the external device.

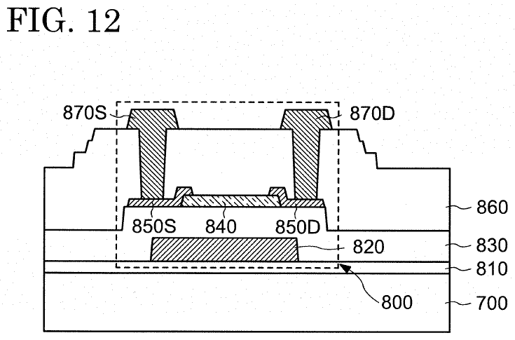

Next, a thin film transistor (TFT) included in the pixel circuit 711, the gate driver circuit 720G, and the source driver circuit 720S are described with reference to FIG. 12.

FIG. 12 is a schematic cross-sectional view of a TFT 800 in the circuit substrate 70 used in the method for transferring the element according to the embodiment of the present invention.

As shown in FIG. 12, the TFT 800 includes a base layer 810, a gate electrode layer 820, a gate insulating layer 830, a semiconductor layer 840, a source electrode layer 850S, a drain electrode layer 850D, a protective layer 860, and a source wiring 870S and a drain wiring layer 870D over the substrate 700.

The gate electrode layer 820, the gate insulating layer 830, and the semiconductor layer 840 are provided in this order over the base layer 810.

The source electrode layer 850S is provided at one end of the semiconductor layer 840, and the drain electrode layer 850D is provided at the other end of the semiconductor layer. The source electrode layer 850S and the drain electrode layer 850D are electrically connected to the semiconductor layer 840 on the upper surface and the side surface of the semiconductor layer 840. The protective layer 860, the source wiring layer 870S, and the drain wiring layer 870D are provided over the semiconductor layer 840, the source electrode layer 850S, and the drain electrode layer 850D. The source wiring layer 870S and the drain wiring layer 870D are connected to the source electrode layer 850S and the drain electrode layer 850D, respectively, through openings provided in the protective layer 860. For convenience of explanation, 850S is referred to as a source electrode layer and 850D is referred to as a drain electrode layer, but the functions of the source electrode layer 850S and the drain electrode layer 850D may be interchanged. Similarly, the functions of the source wiring layer 870S and the drain wiring layer 870D may be interchanged.

For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) can be used as the base layer 810, the gate insulating layer 830, and the protective layer 860. Here, SiOₓN_{y} and AlOₓN_{y} are respectively a silicon compound and an aluminum compound containing nitrogen (N) in an amount smaller than that of oxygen (O). Further, SiNₓO_{y} and AlNₓO_{y} are respectively a silicon compound and an aluminum compound which contain a smaller amount of oxygen than nitrogen.

For example, copper (Cu), aluminum (AI), titanium (Ti), chromium (Cr), cobalt (Co), nickel (Ni), molybdenum (Mo), hafnium (Hf), tantalum (Ta), tungsten (W), bismuth (Bi), or alloys or compounds thereof can be used for the gate electrode layer 820, source electrode layer 850S. drain electrode layer 850D, source wiring layer 870S, and drain wiring layer 870D.

For example, a silicon semiconductor such as amorphous silicon or polysilicon, or an oxide semiconductor such as ZnO or IGZO can be used for the semiconductor layer 840.

Further, although not shown in the figure, an insulating layer for flattening the unevenness of the TFT 800 described above can be provided over the source wiring layer 870S and the drain wiring layer 870D. For example, an organic insulating material such as an acrylic resin or a polyimide resin can be used for the insulating layer to be flattened. An electrode electrically connected to the element 610 can be provided on the insulating layer to be flattened, and is electrically connected to the source electrode layer 850S or the drain electrode layer 850D.

### [3. Transfer Method]

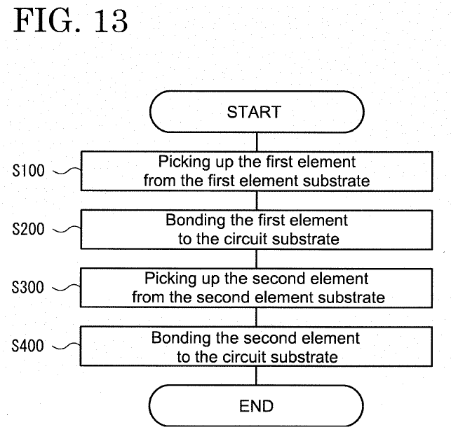

FIG. 13 is a flowchart of the method for transferring the element 610 according to the embodiment of the present invention.

The method for transferring the element according to the present embodiment includes a step of picking up the first element 610R from the first element substrate 60R using the transfer substrate 10 (S100), a step of bonding the picked-up first element 610R to the circuit substrate 70 (S200), a step of picking up the second element 610G from the second element substrate 60G using the transfer substrate 10 (S300), and a step of adhering the picked-up second element 610G to the circuit substrate 70 (S400).

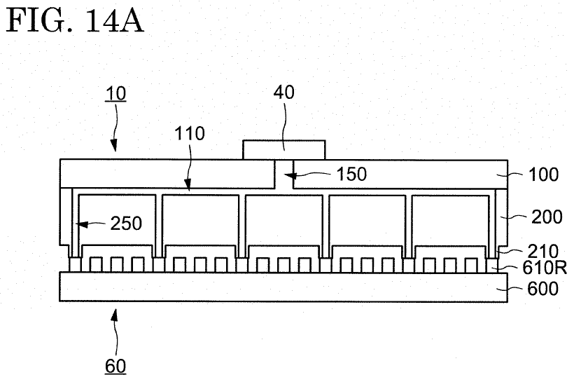

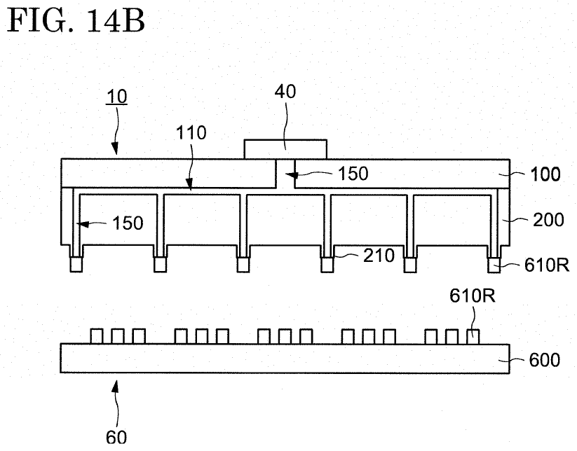

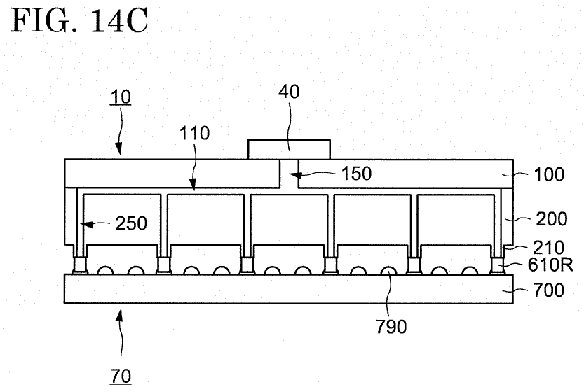

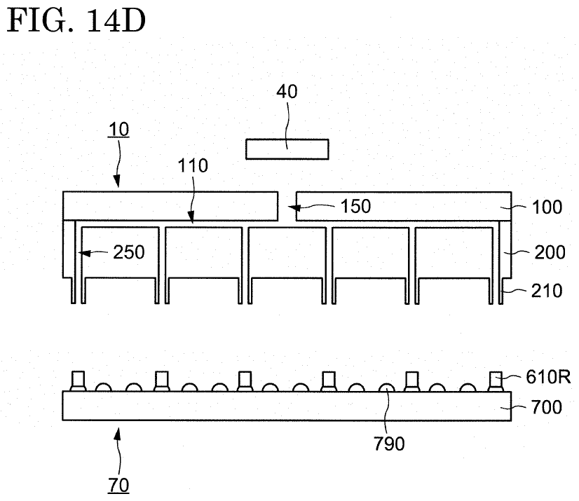

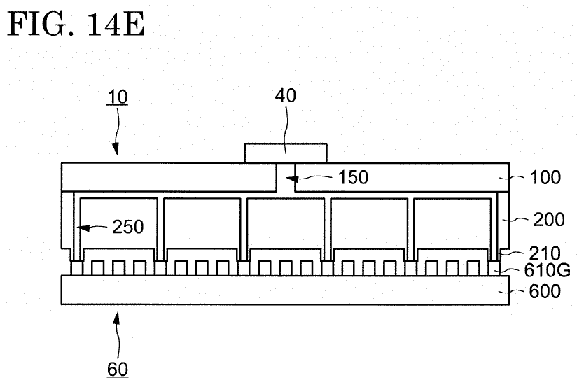

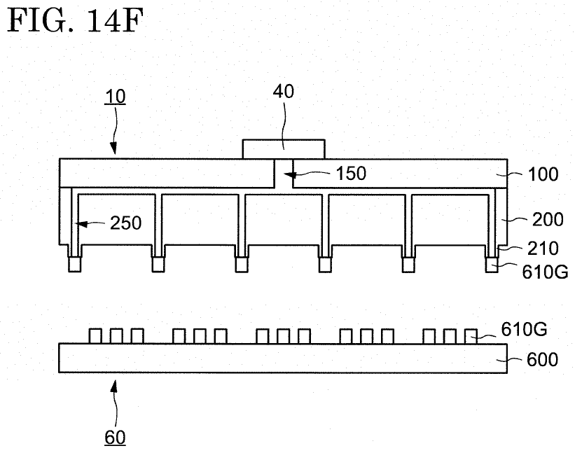

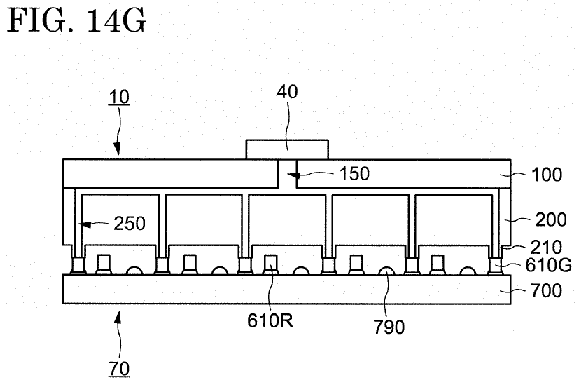

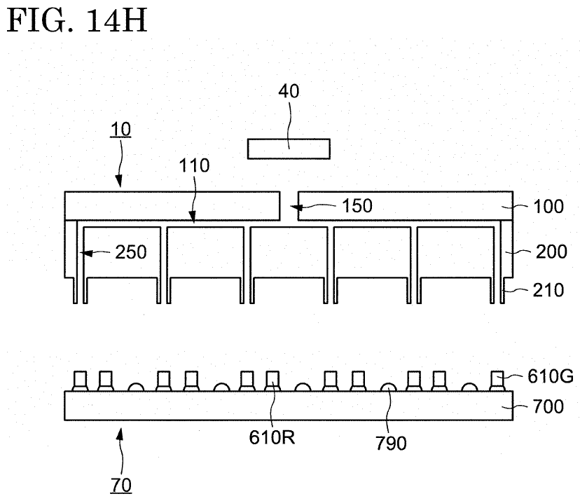

Hereinafter, the method for transferring the element is described in detail with reference to FIGS. 14A to 14H and 15.

FIGS. 14A to 14H are schematic cross-sectional views showing the method for transferring the element according to the embodiment of the present invention.

FIG. 14A shows a state in which the transfer substrate 10 is pressed against the first element substrate 60R in step S100. The head surface 211 of the projection portion 210 is in contact with the first element 610R of the first element substrate 60R so as to close the second opening portion 250 of the transfer substrate 10. Further, the projection portion 210 is compressed by receiving a repulsive force from the first element 610R. Therefore, the length (height) of the projection portion 210 in this state is smaller than the length of the projection portion 210 in a normal state. Furthermore, the cap 40 closes the first opening portion 150 of the support 100 Therefore, the space inside the transfer substrate 10 is sealed and the pressure is reduced.

FIG. 14B shows a state in which the transfer substrate 10 is separated from the first element substrate 60R in step S100. The adhesive force of the projection portion 210 with respect to the first element 610R is larger than the adhesive force between the first element 610R and the support substrate 600. Therefore, the first element 610R, which is in contact with the projection portion 210, is separated from the support substrate 600 and is picked up by the projection portion 210 of the transfer substrate 10. Since the space inside the transfer substrate 10 is under reduced pressure, the first element 610R does not separate from the transfer substrate 10.

FIG. 14C shows a state in which the transfer substrate 10 having picked-up the first element 610R is pressed against the circuit substrate 70 in step S200. The circuit substrate 70 is provided with a conductive adhesive 790. The conductive adhesive 790 is, for example, an adhesive containing a conductive filler. Further, the conductive adhesive 790 may be a thermosetting adhesive or a photocurable adhesive. The conductive adhesive 790 fixes the first element 610R to the circuit substrate 70 and electrically connects the first element 610R and the wiring provided on the circuit substrate 70.

The first element 610R picked-up by the transfer substrate 10 is in contact with the conductive adhesive 790. There are some variations in the size and height of the conductive adhesive 790. Therefore, in order to bond the first element 610R to the circuit substrate 70 in consideration of the variation in the conductive adhesive 790, it is necessary to apply a certain amount of force to press the transfer substrate 10 against the circuit substrate 70.

FIG. 14D shows a state in which the transfer substrate 10 is separated from the circuit substrate 70 in step S200. When the cap 40 is removed from the first opening portion 150, the pressure inside the transfer substrate 10 returns to atmospheric pressure. The first element 610R is separated from the head surface 211 of the transfer substrate 10 and is bonded to the conductive adhesive 790. That is, the first element 610R is transferred from the transfer substrate 10 to the circuit substrate 70. Further, the length of the projection portion 210 returns to the length in the normal state.

FIG. 14E shows a state in which the transfer substrate 10 is pressed against the second element substrate 60G in step S100. The head surface 211 of the projection portion 210 is in contact with the second element 610G of the second element substrate 60G so as to close the second opening portion 250 of the transfer substrate 10. Further, the projection portion 210 is compressed by receiving a repulsive force from the second element 610G. Therefore, the length of the projection portion 210 in this state is smaller than the length of the projection portion 210 in the normal state. Furthermore, the cap 40 closes the first opening portion 150 of the support 100 Therefore, the space inside the transfer substrate 10 is sealed and the pressure is reduced. The transfer substrate 10 used in step S300 does not have to be the same as the transfer substrate 10 that picks up the first element 610R. Another transfer substrate 10 may be used for picking up the second element 610G.

FIG. 14F shows a state in which the transfer substrate 10 is separated from the second element substrate 60G in step S300. The adhesive force of the projection portion 210 with respect to the second element 610G is larger than the adhesive force between the second element 610G and the support substrate 600. Therefore, the second element 610G, which is in contact with the projection portion 210, is separated from the support substrate 600 and is picked up by the projection portion 210 of the transfer substrate 10. Since the space inside the transfer substrate 10 is under reduced pressure, the second element 610G does not separate from the transfer substrate 10.

FIG. 14G shows a state in which the transfer substrate 10 having picked-up the second element 610G is pressed against the circuit substrate 70 in step S400. The second element 610G is in contact with the conductive adhesive 790 to which the first element 610R is not bonded. Also, the transfer substrate 10 is pressed against the circuit substrate 70 by applying a certain amount of force.

FIG. 14H shows a state in which the transfer substrate 10 is separated from the circuit substrate 70 in step S400. When the cap 40 is removed from the first opening portion 150, the pressure inside the transfer substrate 10 returns to atmospheric pressure. The second element 610G is separated from the head surface 211 of the transfer substrate 10 and is bonded to the conductive adhesive 790. That is, the second element 610G is transferred from the transfer substrate 10 to the circuit substrate 70. Further, the length of the projection portion 210 returns to the length in the normal state.

The same steps can be repeated to pick up the third element 610B from the third element substrate 60B using the transfer substrate 10, and to bond the picked-up third element 610B to the circuit substrate 70. By using the first element 610R as a red micro LED, the second element 610G as a green micro LED, and the third element 610B as a blue micro LED and bonding the first element 610R, the second element 610G, and the third element in the pixels of the circuit substrate 70, a full-color display device can be obtained.

Further, the first element 610R, the second element 610G, and the third element 610B are used as micro ultraviolet LEDs, and a red phosphor, a green phosphor, and a blue phosphor are provided on the side where light is emitted from the micro ultraviolet LED to convert the emitted ultraviolet light with a phosphor so that a full-color display device can be obtained.

In the method for transferring the element according to the embodiment of the present invention, the pressure of the space in the transfer substrate 10 can be adjusted without using a large-scale vacuum apparatus, and the element can be picked up or released. Therefore, a semiconductor device including an element, for example, a micro LED display device can be manufactured at low cost.

Each of the embodiments described above as an embodiment of the present invention can be appropriately combined and implemented as long as they do not contradict each other. Additions, deletion, or design changes of constituent elements, or additions, omissions, or changes to conditions of steps as appropriate based on the respective embodiments are also included within the scope of the present invention as long as the gist of the present invention is provided.

Other effects of the action which differ from those brought about by each of the above described embodiments, but which are apparent from the description herein or which can be readily predicted by those skilled in the art, are naturally understood to be brought about by the present invention.

What is claimed is:

1. A transfer substrate for an element comprising:
a support comprising:
a first surface comprising a first opening portion; and
a second surface located on an opposite side of the first surface and having a groove portion; and
an elastic body comprising:
a third surface closing an upper surface of the groove portion; and
a fourth surface located on an opposite side of the third surface and comprising a plurality of projection portions,
wherein each of the plurality of projection portions comprises a second opening portion, and
the first opening portion and the second opening portion are penetrated via the groove portion.

2. The transfer substrate for an element according to claim 1, further comprising a means for closing the first opening portion.

3. The transfer substrate for an element according to claim 1,
wherein a depth of the groove portion is less than or equal to ½ of a thickness of the support.

4. The transfer substrate for an element according to claim 1,
wherein a width of the groove portion is greater than a diameter of the first opening portion and a diameter of the second opening portion.

5. The transfer substrate for an element according to claim 1,
wherein the groove portion comprises a curved portion provided in a curved shape.

6. The transfer substrate for an element according to claim 1,
wherein the groove portion comprises a first straight line portion and a second straight line portion each provided in a straight line.

7. The transfer substrate for an element according to claim 6,
wherein the first straight line portion and the second straight line portion are orthogonal.

8. The transfer substrate for an element according to claim 7,
wherein a width of an intersection of the first straight line portion and the second straight line portion is greater than a width of the first straight line portion and a width of the second straight line portion.

9. The transfer substrate for an element according to claim 6,
wherein the first straight line is located inside the support more than the second straight line portion, and
a width of the first straight line portion is greater than a width of the second straight line portion.

10. The transfer substrate for an element according to claim 1,
wherein the groove portion comprises a tapered shape.

11. A transfer substrate for an element comprising:
a support comprising:
a first surface comprising a first opening portion and a second opening portion; and
a second surface located on an opposite side of the first surface and comprising a first groove portion and a second groove portion; and
an elastic body comprising:
a third surface closing an upper surface of the first groove portion and an upper surface of the second groove portion; and
a fourth surface located on an opposite side of the third surface and comprising a first projection portion and a second projection portion,
wherein the first projection portion comprises a third opening portion,
the second projection portion comprises a fourth opening portion,
the first opening portion and the third opening portion are penetrated via the first groove portion, and
the second opening portion and the fourth opening portion are penetrated via the second groove portion.

12. The transfer substrate for an element according to claim 11, further comprising a means for closing the first opening portion and the second portion.

13. The transfer substrate for an element according to claim 11,
wherein each of a depth of the first groove portion and a depth of the second groove portion is less than or equal to ½ of a thickness of the support.

14. The transfer substrate for an element according to claim 11,
wherein a width of the first groove portion is greater than a diameter of the first opening portion, and
a width of the second groove portion is greater than a diameter of the second opening portion.

15. The transfer substrate for an element according to claim 11,
wherein one of the first groove portion and the second groove portion comprises a curved portion provided in a curved shape.

16. The transfer substrate for an element according to claim 11,
wherein each of the first groove portion and the second groove portion comprises a first straight line portion and a second straight line portion each provided in a straight line.

17. The transfer substrate for an element according to claim 16,
wherein the first straight line portion and the second straight line portion are orthogonal.

18. The transfer substrate for an element according to claim 17,
wherein a width of an intersection of the first straight line portion and the second straight line portion is greater than a width of the first straight line portion and a width of the second straight line portion.

19. The transfer substrate for an element according to claim 16,
wherein the first straight line is located inside the support more than the second straight line portion, and
a width of the first straight line portion is greater than a width of the second straight line portion.

20. The transfer substrate for an element according to claim 11,
wherein each of the first groove portion and the second groove portion comprises a tapered shape.
